(19) United States
(12) Patent Application Publication
(10) Pub. No.: US 2015/0114698 A1
(43) Pub. Date: Apr. 30, 2015

(54) SUBSTRATE STRUCTURE AND MANUFACTURING METHOD THEREOF

(71) Applicants: Tzu-Wei Huang, Hsinchu County (TW); Chin-Sheng Wang, Hsinchu County (TW)

(72) Inventors: Tzu-Wei Huang, Hsinchu County (TW); Chin-Sheng Wang, Hsinchu County (TW)

(73) Assignee: SUBTRON TECHNOLOGY CO., LTD., Hsinchu County (TW)

(21) Appl. No.: 14/105,195

(22) Filed: Dec. 13, 2013

(30) Foreign Application Priority Data
Oct. 30, 2013 (TW) 102139367

(51) Int. Cl. H05K 1/11; H05K 3/00; H05K 3/42; H05K 1/09

(52) U.S. Cl. CPC H05K 1/115; H05K 1/09; H05K 3/0094; H05K 3/421; H05K 2201/09509
USPC 174/257; 29/17.3

(57) ABSTRACT

A substrate structure includes a substrate and a filling material. The substrate has an upper surface, a lower surface, at least one first blind via and at least one second blind via. The substrate includes an insulation layer, a first copper foil layer and a second copper foil layer. The first copper foil layer and the second copper foil layer are respectively disposed on two opposite side surfaces of the insulation layer. The first blind via extends from the upper surface toward the second copper foil layer and exposes a portion of the second copper foil layer. The second blind via extends from the lower surface toward the first copper foil layer and exposes a portion of the first copper foil layer. The filling material is filled inside of the first blind via and the second blind via and covers the upper surface and the lower surface of the substrate.

### CROSS-REFERENCE TO RELATED APPLICATION

This application claims the priority benefit of Taiwan application serial no. 102139367, filed on Oct. 30, 2013. The entirety of the above-mentioned patent application is hereby incorporated by reference herein and made a part of this specification.

### BACKGROUND OF THE INVENTION

1. Field of the Invention

The invention relates to a substrate structure and manufacturing method thereof. More particularly, the invention relates to a substrate structure having a plated via-filling structure and manufacturing method thereof.

2. Description of Related Art

Generally, when the conductive via structure is about to be formed on a substrate composed of an insulation layer and two copper foil layers, the blind via is first formed on one side of the substrate by such as laser drilling to expose the copper foil layer under the insulation layer. Then, a copper layer is electroplated in the blind via and on the upper copper foil layer through an electroplating via-filling method, so as to form another circuit layer and the conductive via.

However, when the electroplating via-filling process is performed, the plated copper layers are not only formed inside of the blind via and on the upper cooper layer foil, but also on the lower copper foil layer. Due to the surface area of one side of the substrate with blind via is greater than that of the other side of the substrate with the lower copper foil layer, therefore, after performing the electroplating via-filling process, the pitting phenomenon is prone to occur in the plated copper layer on the blind via, and the plated copper layer formed on the lower copper foil layer will have an over thickness. As a result, not only the process of reducing the over thickness of the plated copper layer is needed, but it is also required to conduct the flatness process to the pitting plated copper layer. Hence, the costs required for the above manufacturing method is higher and the manufacturing steps are more complex.

### SUMMARY OF THE INVENTION

Accordingly, the invention is directed to a substrate structure and manufacturing method thereof, which can improve the process yield and reduce manufacturing cost, also further enhance the product reliability.

The invention provides a substrate structure including a substrate and a filling material. The substrate has an upper surface and a lower surface opposite to each other, at least one first blind via and at least one second blind via. The substrate includes an insulation layer, a first copper foil layer and a second copper foil layer. The first copper foil layer and the second copper foil layer are respectively located on two opposite side surfaces of the insulation layer, and the first copper foil layer and the second copper foil layer have the upper surface and the lower surface respectively. The first blind via extends from the upper surface toward the second copper foil layer and exposes a portion of the second copper foil layer. The second blind via extends from the lower surface toward the first copper foil layer and exposes a portion of the first copper foil layer. The filling material is filled inside of the first blind via and the second blind via and covers the upper surface and the lower surface of the substrate.

According to an embodiment of the invention, the at least one first blind via is a plurality of first blind vias, and the at least one second blind via is a plurality of second blind vias. The first blind vias and the second blind vias are arranged alternatively.

According to an embodiment of the invention, a diameter of the first blind via is gradually reduced from the upper surface toward the second copper foil layer, and a diameter of the second blind via is gradually reduced from the lower surface toward the first copper foil layer.

According to an embodiment of the invention, a cross-sectional profile of the first blind via is an inverse-trapezoidal, and a cross-sectional profile of the second blind via is an upright-trapezoidal.

According to an embodiment of the invention, the filling material is a conductive material, and the filling material is electrically connected to the first copper foil layer and the second copper foil layer.

The invention provides a manufacturing method of a substrate structure including following procedures. A substrate is provided. The substrate has an upper surface and a lower surface opposite to each other. The substrate includes an insulation layer, a first copper foil layer and a second copper foil layer. The first copper foil layer and the second copper foil layer are respectively located on two opposite side surfaces of the insulation layer. The first copper foil layer and the second copper foil layer have the upper surface and the lower surface respectively. A first through-hole process is performed on the upper surface of the substrate to form at least one first blind via extending from the upper surface toward the second copper foil layer and exposing a portion of the second copper foil layer. A second through-hole process is performed on the lower surface of the substrate to form at least one second blind via extending from the lower surface toward the first copper foil layer and exposing a portion of the first copper foil layer. A filling material is plated inside of the first blind via and the second blind via. The filling material is filled up the first blind via and the second blind via and covers the upper surface and the lower surface of the substrate.

According to an embodiment of the invention, the first through-hole process includes laser machining, mechanical drilling, and chemical etching.

According to an embodiment of the invention, the second through-hole process includes laser machining, mechanical drilling and chemical etching.

According to an embodiment of the invention, a diameter of the first blind via is gradually reduced from the upper surface toward the second copper foil layer. A diameter of the second blind via is gradually reduced from the lower surface toward the first copper foil layer.

According to an embodiment of the invention, a cross-sectional profile of the first blind via is an inverse-trapezoidal, and a cross-sectional profile of the second blind via is an upright-trapezoidal.

According to the above description, due to the first blind via and the second blind via are respectively formed on the upper surface and the lower surface of the substrate in the present invention, in the subsequent, when a filling material is plated, the plated areas on the upper surface and the lower surface are similar, thus, the filling material can be uniformly filled in the first blind via formed on the upper surface and the second blind via formed on the lower surface and cover the upper surface and the lower surface. In comparison with the method for forming the blind via on one side surface of the conventional substrate and than forming the conductive via in the blind via by plating, the manufacturing method of the substrate structure of the invention can improve the process yield of conductive vias and reduce manufacturing cost, also further enhance the product reliability.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic partial cross-sectional view illustrating a substrate structure according to an embodiment of the invention.

FIG. 1B is a schematic top view illustrating a substrate structure depicted in FIG. 1A according to an embodiment of the invention.

FIG. 1C is a schematic top view illustrating of a substrate structure depicted in FIG. 1A according to another embodiment of the invention.

FIG. 2A to FIG. 2C are schematic cross-sectional views illustrating a manufacturing method of a substrate structure according to an embodiment of the invention.

### DESCRIPTION OF EMBODIMENTS

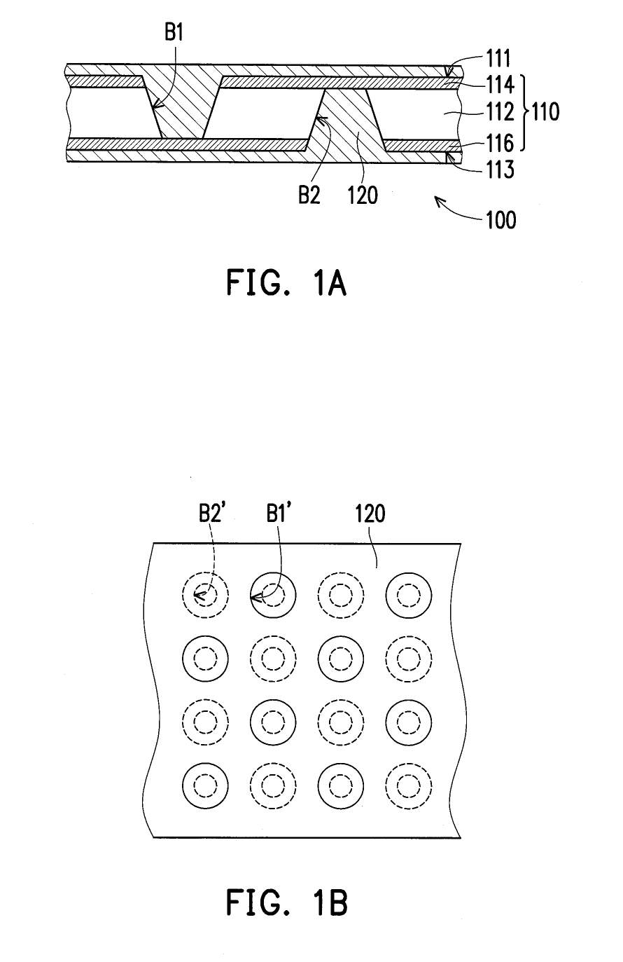

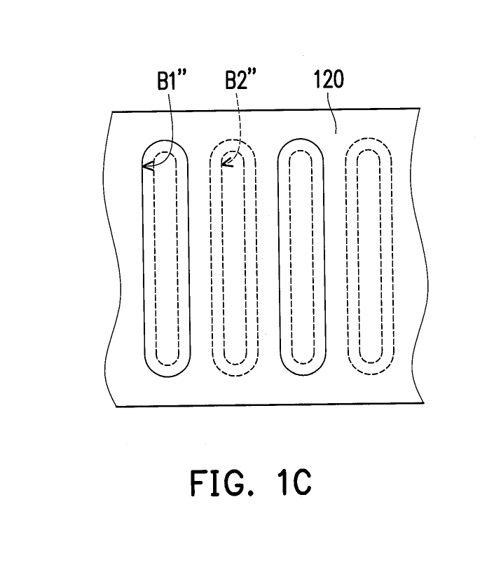

FIG. 1A is a schematic partial cross-sectional view illustrating a substrate structure according to an embodiment of the invention. Referring to FIG. 1A, in the present embodiment, the substrate structure 100 includes a substrate 110 and a filling material 120. The substrate 110 has an upper surface 111 and a lower surface 113 opposite to each other, at least one first blind via B1 and at least one second blind via B2. The substrate 110 includes an insulation layer 112, a first copper foil layer 114 and a second copper foil layer 116. The first copper foil layer 114 and the second copper foil layer 116 are respectively located on two opposite side surfaces of the insulation layer 112. The first copper foil layer 114 and the second copper foil layer 116 have the upper surface 111 and the lower surface 113 respectively. The first blind via B1 extends from the upper surface 111 toward the second copper foil layer 116 and exposes a portion of the second copper foil layer 116. The second blind via B2 extends from the lower surface 113 toward the first copper foil layer 114 and exposes a portion of the first copper foil layer 114. The filling material 120 is filled inside of the first blind via B1 and the second blind via B2, and covers the upper surface 111 and the lower surface 113 of the substrate 110.

More specifically, as shown in FIG. 1A, a diameter of the first blind via B1 is gradually reduced from the upper surface 111 toward the second copper foil layer 116. A diameter of the second blind via B2 is gradually reduced from the lower surface 113 toward the first copper foil layer 114. That is, a cross-sectional profile of the first blind via B1 of the present embodiment is specified as an inverse-trapezoidal, and a cross-sectional profile of the second blind via B2 is specified as an upright-trapezoidal. Certainly, in another embodiment (not illustrated), the cross-sectional profiles of the first blind via and the second blind via also may be the rectangles or other desirable shapes. Moreover, the filling material 120 of the present embodiment is specified as a conductive material, wherein the filling material 120 is electrically connected to the first copper foil layer 114 and the second copper foil layer 116. Followed by patterning the filling material 120 located on the first copper foil layer 114 and the second copper foil layer 116, a circuit board structure with the conductive vias can be formed. In other words, the substrate structure 100 of the present embodiment is a semi-finished product of a circuit board structure.

On the other hand, as shown in FIG. 1A, although the amount of the first blind via B1 and the second blind via B2 both are one respectively, in another embodiment, the amount of the first blind via B1 and the second blind via B2 of the substrate structure 100 may be multiple. As shown in FIG. 1B, a plurality of first blind vias B1′ and a plurality of second blind vias B2′ are arranged alternatively, and the opening shapes of the first blind vias B1′ and the second blind vias B2′ are specified as circular shape, or otherwise, as shown in FIG. 1C a plurality of first blind vias B1″ and a plurality of second blind vias B2″ are arranged alternatively, and the opening shapes of the first blind vias B1″ and the second blind vias B2″ are specified as elliptical shape. All aforementioned are the technical schemes that can be used for the invention without departing from its desired scope of protection. Certainly, the opening shapes of the first blind vias B1′, B1″ and second blind vias B2′, B2″ of the invention are not limited thereto, the important herein is the structure formed the first blind via B1 and the second blind via B2 on the upper surface 111 and the lower surface 113 of the substrate 110 respectively by design, and all the structures belong to the schemes adopted by the invention without departing from the claims of the invention.

Due to the first blind via B1 and the second blind B2 are formed on the upper surface 111 and the lower surface 113 on the substrate 110 respectively, and the filling material 120 is filled inside of the first blind via B1 and the second blind via B2 and covers the upper surface 111 and the lower surface 113 of the substrate 110. Accordingly, two opposite sides of the substrate structure 100 of the present embodiment can sustain the same amount of strain and thus have the better structure reliability.

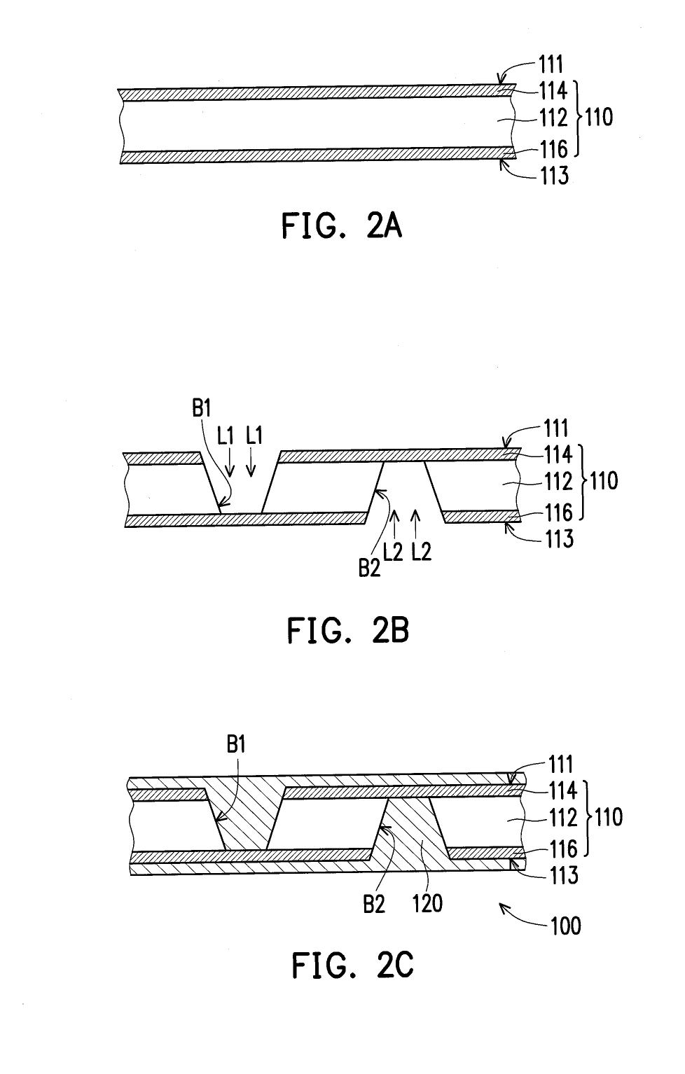

Up to here, only the structure of the substrate structure 100 of the present invention is described, while a process of fabricating the substrate structure 100 of the present invention is not yet provided. In the following, a manufacturing method is depicted with accompanying diagrams of FIG. 2A to FIG. 2C, wherein the substrate structure 100 is taken as an example.

FIG. 2A to FIG. 2C are schematic cross-sectional views illustrating a manufacturing method of a substrate structure according to an embodiment of the invention. First referring to FIG. 2A, according to the manufacturing method of the substrate structure of the present embodiment, first, a substrate 110 is provided. The substrate 110 has an upper surface 111 and a lower surface 113 opposite to each other. The substrate 110 includes an insulation layer 112, a first copper foil layer 114 and a second copper foil layer 116. The first copper foil layer 114 and the second copper foil layer 116 are respectively located on two opposite side surfaces of the insulation layer 112. The first copper foil layer 114 and the second copper foil layer 116 have the upper surface 111 and the lower surface 113 respectively.

Then, referring to FIG. 2B, a first through-hole process is performed on the upper surface 111 of the substrate 110, so as to form at least one first blind via B1 extending from the upper surface 111 toward the second copper foil layer 116 and exposing a portion of the second copper foil layer 116. Moreover, a second through-hole process is performed on the lower surface 113 of the substrate 110, so as to form at least one second blind via B2 extending from the lower surface 113 toward the first copper foil layer 114 and exposing a portion of first copper foil layer 114. It should be noted that the invention is not limited to the sequence of the first through-hole process and the second through-hole process herein, it may start from the first through-hole process and then the second through-hole process, or the first through-hole process and the second through-hole process may be performed at the same time.

In the present embodiments, the first through-hole process may be laser machining, mechanical drilling or chemical etching, and the second through-hole process may also be laser machining, mechanical drilling or chemical etching. For example, the first through-hole process and the second through-hole process are specified as laser machining, the diameter the first blind via B1 formed on the upper surface 111 of the substrate 110 by a first laser beam L1 is gradually reduced from the upper surface 111 toward the second copper foil layer 116, and the diameter of the second blind via B2 formed on the lower surface 113 of the substrate 110 by a second laser beam L2 is gradually reduced from the lower surface 113 toward the first copper foil layer 114. That is to say, the cross-sectional profile of the first blind via B1 of the present invention is specified as an inverse-trapezoidal, and the cross-sectional profile of the second blind via B2 is specified as an upright-trapezoidal. Certainly, in another embodiment (not illustrated), the cross-sectional profile of the first blind via and the second blind via may also be rectangles or other desirable shapes.

After that, referring to FIG. 2C, a filling material 120 is plated inside of the first blind via B1 and the second blind via B2, wherein the filling material 120 is filled up the first blind via B1 and the second blind via B2 and covers the upper surface 111 and the lower surface 113 of the substrate 110. At this point, the manufacture of the substrate structure 100 has been accomplished.

Due to the first blind via B1 and the second blind via B2 are respectively formed on the upper surface 111 and the lower surface 113 of the substrate 110 of the present embodiment, therefore, in comparison with the conventional substrate having blind vias on one side surface, the contact areas of the upper surface 111 and the lower surface 113 opposite to each other of the substrate 110 are substantially similar during the plating process. Accordingly, the filling material 120 can be formed uniformly on the upper surface 111 and the lower surface 113 of the substrate 110, and filled inside of the first via B1 and the second via B2. As a result, no copper reducing process and flatness process in the prior art are required, and the manufacturing method of the substrate structure 100 of the present embodiment is able to improve the process yield of conductive vias and reduce manufacturing cost, also further enhance the product reliability.

To sum up, due to the first blind via and the second blind via are respectively formed on the upper surface and the lower surface of the substrate in the present invention, in the subsequent, when a filling material is plated, the plated areas on the upper surface and the lower surface of the substrate are similar, therefore, the filling material can be uniformly filled in the first blind via formed on the upper surface and the second blind via formed on the lower surface and cover the upper and the lower surface. In comparison with the method for forming the blind via on one side surface of the conventional substrate and than forming the conductive via in the blind via by plating, the manufacturing method of the substrate structure of the invention can improve the process yield of conductive vias and reduce manufacturing cost, also further enhance the product reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A substrate structure, comprising:
a substrate, having an upper surface and a lower surface opposite to each other, at least one first blind via and at least one second blind via, the substrate comprising an insulation layer, a first copper foil layer and a second copper foil layer, wherein the first copper foil layer and the second copper foil layer are located on two opposite side surfaces of the insulation layer, the first copper foil layer and the second copper foil layer have the upper surface and the lower surface respectively, the first blind via extends from the upper surface toward the second copper foil layer and exposes a portion of the second copper foil layer, and the second blind extends from the lower surface toward the first copper foil layer and exposes a portion of the first copper foil layer; and
a filling material, filled inside of the first blind via and the second blind via and covering the upper surface and the lower surface of the substrate.

2. The substrate structure as recited in claim 1, wherein the at least one first blind via is a plurality of first blind vias, and at least one second blind via is a plurality of second blind vias, the first blind vias and the second blind vias are arranged alternatively.

3. The substrate structure as recited in claim 1, wherein a diameter of the first blind via is gradually reduced from the upper surface toward the second copper foil layer, and a diameter of the second blind via is gradually reduced from the lower surface toward the first copper foil layer.

4. The substrate structure as recited in claim 3, wherein a cross-sectional profile of the first blind via is an inverse-trapezoidal, and a cross-sectional profile of the second blind via is an upright-trapezoidal.

5. The substrate structure as recited in claim 1, wherein the filling material is a conductive material, and the filling material is electrically connected to the first copper foil layer and the second copper foil layer.

6. A manufacturing method of a substrate structure, comprising:
providing a substrate, the substrate having an upper surface and a lower surface opposite to each other, wherein the substrate comprises an insulation layer, a first copper foil layer and a second copper foil layer, the first copper foil layer and the second copper foil layer are respectively located on two opposite side surfaces of the insulation layer, and the first copper foil layer and the second copper foil layer have the upper surface and the lower surface respectively;
performing a first through-hole process on the upper surface of the substrate to form at least one first blind via extending from the upper surface toward the second copper foil layer and exposing a portion of the second copper foil layer;
performing a second through-hole process on the lower surface of the substrate to form at least one second blind via extending from the lower surface toward the first copper foil layer and exposing a portion of the first copper foil layer; and
plating a filling material inside of the first blind via and the second blind via, wherein the filling material is filled up the first blind via and the second blind via and covers the upper surface and the lower surface of the substrate.

7. The manufacturing method of the substrate structure as recited in claim 6, wherein the first through-hole process comprises laser machining, mechanical drilling and chemical etching.

8. The manufacturing method of the substrate structure as recited in claim 6, wherein the second through-hole process comprises laser machining, mechanical drilling and chemical etching.

9. The manufacturing method of the substrate structure as recited in claim 6, wherein a diameter of the first blind via is gradually reduced from the upper surface toward the second copper foil layer, and a diameter of the second blind via is gradually reduced from the lower surface toward the first copper foil layer.

10. The manufacturing method of the substrate structure as recited in claim 9, wherein a cross-sectional profile of the first blind via is an inverse-trapezoidal and a cross-sectional profile of the second blind via is an upright-trapezoidal.
